(19) United States
(12) Patent Application Publication
(10) Pub. No.: US 2015/0087135 A1
(43) Pub. Date: Mar. 26, 2015

(54) METHOD OF FORMING A TRENCH ISOLATION STRUCTURE USING A SION LAYER

(71) Applicant: Texas Instruments Incorporated, Dallas, TX (US)

(72) Inventors: Yaojian Leng, Lake Oswego, OR (US); Scott Allyn Kolda, New Gloucester, ME (US)

(73) Assignee: Texas Instruments Incorporated, Dallas, TX (US)

(21) Appl. No.: 14/479,298

(22) Filed: Sep. 6, 2014

Related U.S. Application Data
(60) Provisional application No. 61/882,878, filed on Sep. 26, 2013.

(51) Int. Cl. H01L 21/762; H01L 21/02

(52) U.S. Cl. CPC H01L 21/76224; H01L 21/0217; H01L 21/02164
USPC 438/424

(57) ABSTRACT

A moat, which is a region of a semiconductor wafer that is laterally surrounded by a trench isolation structure, is protected from damage due to dishing or low spots that result from chemical-mechanical polishing by forming a patterned hard mask structure with an upper silicon oxynitride layer, and performing the polishing with a slurry that includes ceria.

This application claims benefit from Provisional Application No. 61/882,878 filed on Sep. 26, 2013 for Yaojian Leng et al.

### BACKGROUND OF THE INVENTION

1. Field of the Invention

The present invention relates to a method of forming a trench isolation structure and, more particularly, to a method of forming a trench isolation structure using a SiON layer.

2. Description of the Related Art

A trench isolation structure is a semiconductor structure that extends down a distance into a semiconductor wafer from the top surface of the wafer. Trench isolation structures are widely utilized to isolate laterally adjacent devices, such as transistors, resistors, and diodes, due to the small surface area and low parasitic capacitance of the isolation structures.

Trench isolation structures are conventionally formed by depositing a pad oxide layer on the top surface of a conventionally-formed semiconductor wafer, followed by the deposition of a nitride layer on the pad oxide layer. Next, the nitride layer and the underlying pad oxide layer are selectively etched to expose a number of regions on the top surface of the wafer.

After this, the exposed regions on the top surface of the wafer are etched to form a number of trenches that extend down into the wafer. Once the trenches have been formed, a liner oxide layer is formed to line the exposed surfaces of the trenches, followed by the deposition of a fill oxide layer that fills up the trenches and lies over the nitride layer.

To complete the formation of the trench isolation structures, the fill oxide layer is planarized, typically by chemical-mechanical polishing (CMP). With CMP, the fill oxide layer is both chemically reacted and mechanically ground down until the top surface of the fill oxide layer lies substantially in the same plane as the top surface of the nitride layer. After the fill oxide layer has been planarized, the nitride layer is removed. A completed trench isolation structure laterally surrounds a portion of the semiconductor wafer that is commonly known as a moat.

Conventional CMP processes, however, are subject to dishing, a term that refers to the formation of low spots in an otherwise relatively flat surface. When forming trench isolation structures, dishing is particularly problematic when a relatively narrow moat lies a distance away from an adjacent moat.

In this case, due to the absence of nearby moats, the CMP process can dish or form a low spot over the narrow moat where the nitride layer, the pad oxide layer, the surrounding fill oxide layer, and even a portion of the narrow moat itself are undesirably removed. Devices which are then subsequently formed in a moat which has been partially removed due to dishing are frequently inoperable or fail to operate as intended.

If the CMP process is shortened to prevent any part of the narrow moat from being removed, portions of the fill oxide layer can be left on top of the nitride layer that lies over the other moats. As a result, instead of removing all of the nitride layer after the fill oxide layer has been planarized, a part of the nitride layer can be undesirably left on the pad oxide layer.

Thus, there is a need for a method of forming a trench isolation structure that removes all of the fill oxide layer that lies over the nitride layer without removing any part of a moat.

### SUMMARY OF THE INVENTION

The present invention provides a method of forming a trench isolation structure that substantially reduces the effect of dishing that results from chemical-mechanical polishing. The method includes forming a patterned hard mask structure on a top surface of a semiconductor wafer. The patterned hard mask structure has a silicon oxynitride layer, and an opening that exposes a region on the top surface of the semiconductor wafer. The method also includes etching the semiconductor wafer through the opening in the patterned hard mask structure to form a trench in the semiconductor wafer. The method further includes lining the trench with a non-conductive material to form a lined trench, and filling the lined trench with a semiconductor material. The semiconductor material touches the non-conductive material and lies over the patterned hard mask structure. In addition, the method includes chemically-mechanically polishing the semiconductor material.

A method of forming a trench isolation structure alternately includes forming a pad oxide layer on a top surface of a semiconductor wafer. The alternate method also includes forming a silicon nitride layer on the pad oxide layer, and forming a silicon oxynitride layer on the silicon nitride layer. In addition, the alternate method includes forming an opening that extends through the silicon oxynitride layer, the silicon nitride layer, and the pad oxide layer to expose the top surface of the semiconductor wafer. Further, the alternate method includes etching the semiconductor wafer through the opening to form a trench in the semiconductor wafer.

A better understanding of the features and advantages of the present invention will be obtained by reference to the following detailed description and accompanying drawings which set forth an illustrative embodiment in which the principals of the invention are utilized.

### BRIEF DESCRIPTION OF THE DRAWINGS

FIGS. 1A-1F are cross-sectional views illustrating an example of a method 100 of forming a trench isolation structure in accordance with the present invention.

### DETAILED DESCRIPTION OF THE INVENTION

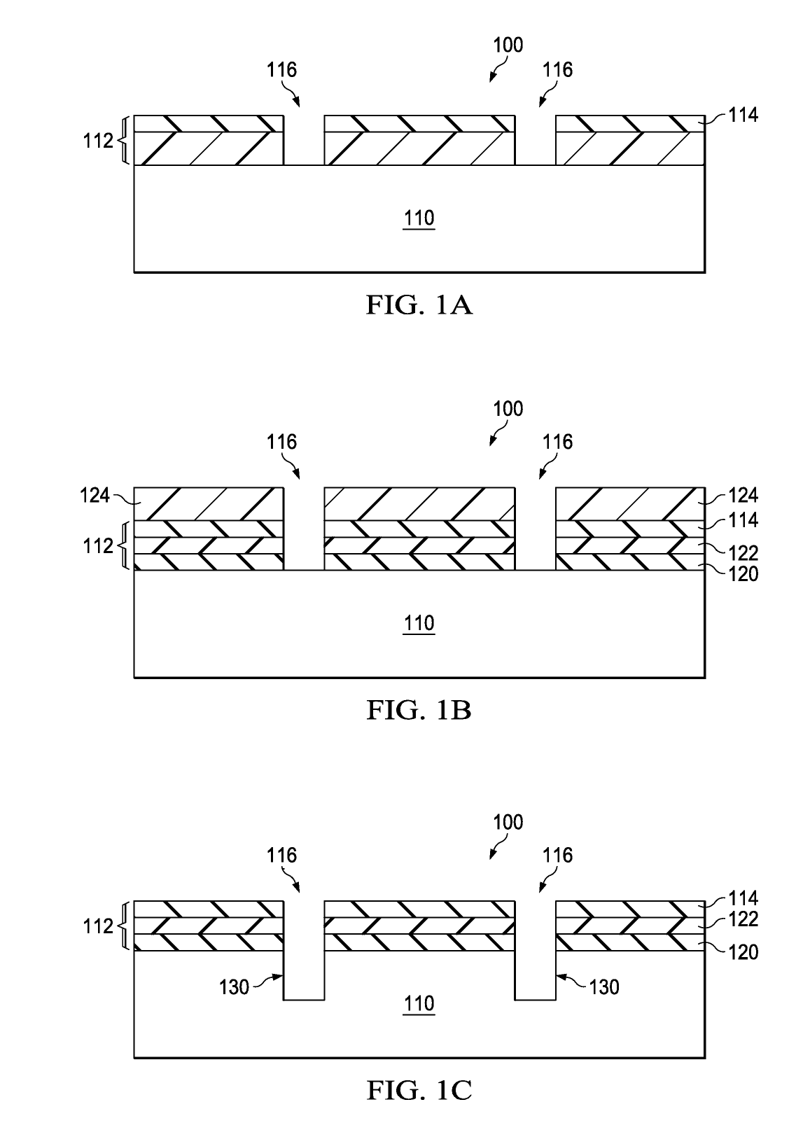

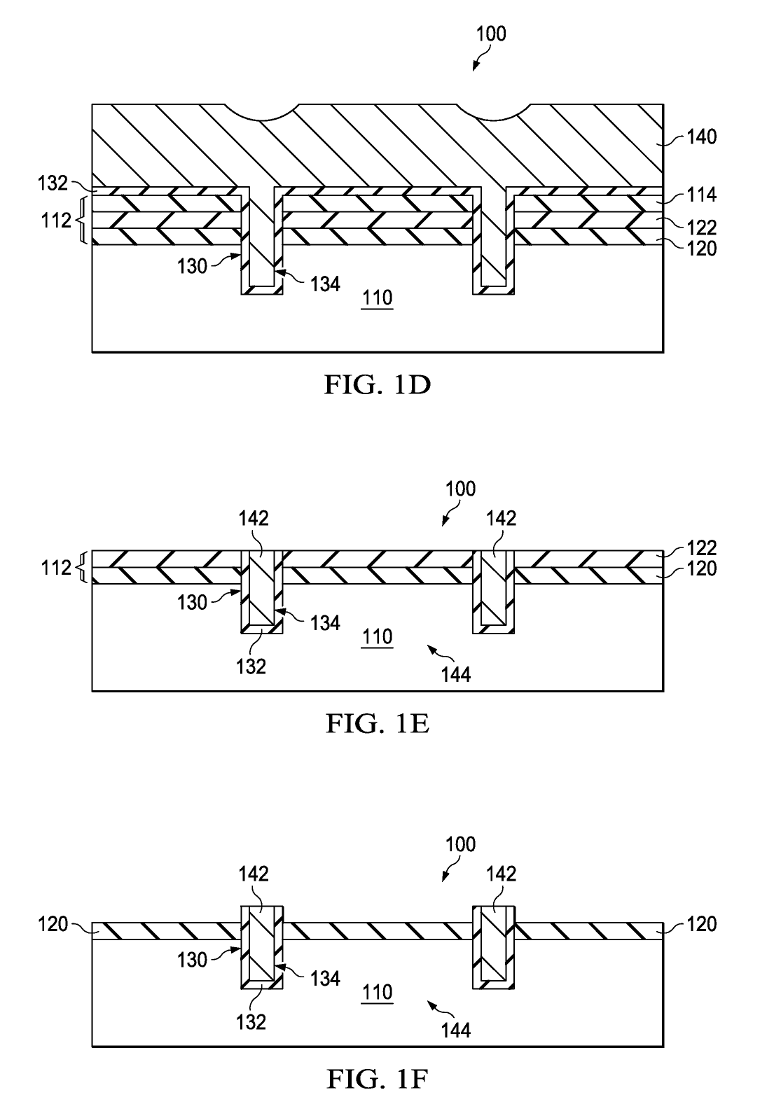

FIGS. 1A-1F show cross-sectional views that illustrate an example of a method 100 of forming a trench isolation structure in accordance with the present invention. As shown in FIG. 1A, method 100, which utilizes a conventionally-formed semiconductor wafer 110, begins by forming a patterned hard mask structure 112 on the top surface of semiconductor wafer 110. Patterned hard mask structure 112 has a silicon oxynitride (SiON) layer 114, and an opening 116 that exposes a region on the top surface of semiconductor wafer 110.

In the present example, as shown in FIG. 1B, patterned hard mask structure 112 is formed by depositing a pad silicon dioxide layer 120 on the top surface of wafer 110, followed by the deposition of a silicon nitride layer 122 on the top surface of pad silicon dioxide layer 120. After silicon nitride layer 122 has been deposited, SiON layer 114 is deposited on the top surface of silicon nitride layer 122.

Pad silicon dioxide layer 120 can be conventionally formed to have a thickness of approximately 110 Å, while silicon nitride layer 122 can be formed with low-pressure chemical vapor deposition (LPCVD) to have a thickness of approximately 1625 Å. In addition, SiON layer 114 can be formed in a conventional fashion to have a thickness of approximately 320 Å.

Next, a patterned photoresist layer 124 is formed on the top surface of SiON layer 114. Patterned photoresist layer 124 is formed in a conventional manner, which includes depositing a layer of photoresist, projecting a light through a patterned black/clear glass plate known as a mask to form a patterned image on the layer of photoresist, and removing the imaged photoresist regions, which were softened by exposure to the light.

After patterned photoresist layer 124 has been formed, the exposed regions of SiON layer 114 and the underlying regions of silicon nitride layer 122 and pad silicon dioxide layer 120 are etched to form opening 116, which exposes a region on the top surface of semiconductor wafer 110. After opening 116 has been formed, patterned photoresist layer 124 is removed in a conventional fashion, such as with an ash process, to complete the formation of patterned hard mask structure 112.

As shown in FIG. 1C, following the formation of patterned hard mask structure 112, the exposed region on the top surface of semiconductor wafer 110 is etched through opening 116 in hard mask structure 112 to form a trench 130 that extends down into wafer 110. In the present example, trench 130 is etched in a conventional manner to have a depth of approximately 4500 Å.

As shown in FIG. 1D, after trench 130 has been formed, the exposed surface of trench 130 is lined with a non-conductive material 132 to form a lined trench 134. Following this, lined trench 134 is filled with a semiconductor material 140 that touches the non-conductive material 132 and lies over patterned hard mask structure 112.

In the present example, non-conductive material 132 is implemented with silicon dioxide, and trench 130 is lined with silicon dioxide in a conventional manner to have a thickness of approximately 200 Å. Semiconductor material 140 can be implemented with a number of materials, such as silicon dioxide or polysilicon, and lined trench 134 is filled in a conventional fashion to have a thickness of approximately 6844 Å.

Next, as shown in FIG. 1E, semiconductor material 140 and SiON layer 114 are chemically-mechanically polished in a conventional manner with a slurry that includes ceria (CeO₂) to form a trench isolation structure 142 that laterally surrounds a moat 144. (Wafer 110 can include a large number of moats 144. FIG. 1E shows a single moat 144 for simplicity.) Ceria possesses a chemical tooth that expedites the removal of semiconductor material 140 and the transport away of the by-products of the polishing.

SiON layer 114, in turn, is easily removed with the ceria slurry. The CMP removal of SiON layer 114 has a polish by-product that includes a significant amount of nitrogen. The nitrogen in the polish by-product from SiON layer 114 then interacts with the ceria slurry to retard the chemical tooth of the slurry which, in turn, substantially reduces the rate that semiconductor material 140 is removed. (Silicon nitride layer 122 does not provide the same benefit as SiON layer 114 because the polishing rate of silicon nitride layer 122 is too low to provide a significant amount of the nitrogen containing by-product.)

Thus, when a relatively narrow moat lies a distance away from an adjacent moat, and the SiON layer 114 that overlies the relatively narrow moat is removed, the nitrogen in the polish by-product provides a temporary polishing stop. As a result, the remaining portion of patterned hard mask structure 112 that lies above the relatively narrow moat as well as the semiconductor material 140 in the surrounding trench isolation structure 142 remain largely intact.

In addition, the temporary polishing stop is initially localized to those moats which previously had been damaged by the CMP dishing. As a result, the semiconductor material 140 on the remaining parts of semiconductor wafer 110 continues to be removed at the same time that the removal of the semiconductor material 140 in the trench isolation structure 142 that surrounds the relatively narrow moat has largely stopped. As the SiON layer 114 on the remaining parts of wafer 110 is removed, the nitrogen by-product provides a temporary polishing stop across wafer 110.

Although the polishing stop provided by the nitrogen by-product is temporary, the polishing stop provides a relatively wide process window in which to stop the CMP process. In the present example, the process window is approximately 25 seconds. When the CMP process stops, the top surface of semiconductor material 140 lies substantially in the same plane as the top surface of the remaining portion of patterned hard mask structure 112. For example, when patterned hard mask structure 112 includes silicon nitride layer 122, the top surface of semiconductor material 140 lies substantially in the same plane as the top surface of silicon nitride layer 122 when the CMP process stops.

After semiconductor material 140 has been planarized such that the top surface of semiconductor material 140 lies in substantially in the same plane as the remaining portion of patterned hard mask structure 112 (or the top surface of silicon nitride layer 122), all or part of the remaining portion of patterned hard mask structure 112 is removed. For example, as shown in FIG. 1F, silicon nitride layer 122 can be removed in a conventional manner, such as with a hot phosphoric acid dip. Method 100 then continues with conventional semiconductor processing steps.

Thus, one of the advantages of the present invention is that the moats which previously had been damaged by CMP dishing are now protected. In addition, the depths of the trench isolation structures 142 across wafer 110, as well as from wafer to wafer, are substantially uniform.

Further, CMP consumable variations from polishing pads, conditioning disks, polishing heads, and slurry are also reduced or eliminated from the post CMP thickness. SiON layer 114 can also be used as an inorganic bottom anti-reflective coating (BARC) to improve photo process margin. Method 100 also has good Cpk (process capability index—how well method 100 fabricates trench isolation structures 142 within specification limits).

It should be understood that the above descriptions are examples of the present invention, and that various alternatives of the invention described herein may be employed in practicing the invention. Thus, it is intended that the following claims define the scope of the invention and that structures and methods within the scope of these claims and their equivalents be covered thereby.

What is claimed is:

1. A method of forming a trench isolation structure comprising:
forming a patterned hard mask structure on a top surface of a semiconductor wafer, the patterned hard mask structure having a silicon oxynitride layer, and an opening that exposes a region on the top surface of the semiconductor wafer;
etching the semiconductor wafer through the opening in the patterned hard mask structure to form a trench in the semiconductor wafer;
lining the trench with a non-conductive material to form a lined trench;
filling the lined trench with a semiconductor material, the semiconductor material touching the non-conductive material and lying over the patterned hard mask structure; and
chemically-mechanically polishing the semiconductor material.

2. The method of claim 1 wherein the patterned hard mask structure includes a silicon nitride layer that touches and lies below the silicon oxynitride layer.

3. The method of claim 2 wherein the patterned hard mask structure includes a silicon dioxide layer that touches and lies below the silicon nitride layer, and touches and lies above the semiconductor wafer.

4. The method of claim 1 wherein the non-conductive material includes silicon dioxide.

5. The method of claim 1 wherein the semiconductor material includes silicon dioxide.

6. The method of claim 1 wherein the semiconductor material includes polysilicon.

7. The method of claim 1 wherein the semiconductor material is chemically-mechanically polished with a slurry that includes ceria.

8. The method of claim 2 and further comprising chemically-mechanically polishing the silicon oxynitride layer until a top surface of the semiconductor material lies substantially in a same plane as a top surface of the silicon nitride layer.

9. The method of claim 8 wherein the silicon oxynitride layer is chemically-mechanically polished with the slurry that includes ceria.

10. The method of claim 9 and further comprising removing the silicon nitride layer after the semiconductor material has been polished so that the top surface of the semiconductor material lies substantially in the same plane as the top surface of the silicon nitride layer.

11. A method of forming a trench isolation structure comprising:
forming a pad oxide layer on a top surface of a semiconductor wafer;
forming a silicon nitride layer on the pad oxide layer;
forming a silicon oxynitride layer on the silicon nitride layer;
forming an opening that extends through the silicon oxynitride layer, the silicon nitride layer, and the pad oxide layer to expose the top surface of the semiconductor wafer; and
etching the semiconductor wafer through the opening to form a trench in the semiconductor wafer.

12. The method of claim 11 and further comprising:
filling the trench with silicon dioxide, the silicon dioxide touching and lying over the silicon oxynitride layer; and
chemically-mechanically polishing the silicon dioxide and the silicon oxynitride layer until a top surface of the silicon dioxide lies substantially in a same plane as a top surface of the silicon nitride layer.

13. The method of claim 12 wherein the silicon dioxide and the silicon oxynitride layer are chemically-mechanically polished with a slurry that includes ceria.

14. The method of claim 13 wherein filling the trench with silicon dioxide includes:
lining the trench with silicon dioxide to form a lined trench; and
depositing silicon dioxide to fill the lined trench and lie over the silicon oxynitride layer.

15. The method of claim 14 and further comprising removing the silicon nitride layer after the silicon dioxide has been polished so that the top surface of the silicon dioxide lies substantially in the same plane as the top surface of the silicon nitride layer.
